(19) United States
(12) Patent Application Publication
(10) Pub. No.: US 2023/0023759 A1
(43) Pub. Date: Jan. 26, 2023

(54) OPTOELECTRONIC COMPONENT AND METHOD FOR PRODUCING THE SAME

(71) Applicant: OSRAM Opto Semiconductors GmbH, Regensburg (DE)

(72) Inventor: Jens Ebbecke, Rohr In Niederbayern (DE)

(21) Appl. No.: 17/777,873

(22) PCT Filed: Nov. 3, 2020
(86) PCT No.: PCT/EP2020/080735

§ 371 Date: May 18, 2022

(30) Foreign Application Priority Data
Nov. 21, 2019 (DE) 102019131422.4

(51) Int. Cl. H01L 33/06; H01L 33/24

(52) U.S. Cl. CPC H01L 33/06; H01L 33/24

(57) ABSTRACT

An optoelectronic component (10) is specified, comprising a semiconductor body (6) with an active region (4) suitable for emission of radiation and comprising a quantum well structure, wherein the quantum well structure comprises at least one quantum well layer (41) and barrier layers (42), a first electrical contact (1) and a second electrical contact (2), wherein the active region (4) comprises at least one intermixed region (44) and at least one non-intermixed region (43).

The at least one quantum well layer (41) and the barrier layers (42) are at least partially intermixed in the intermixed region (44), such that the intermixed region (44) comprises a larger electronic bandgap than the at least one quantum well layer (41) in the non-intermixed region (43). The first electrical contact (1) is a metal contact arranged on a radiation exit surface of the semiconductor body (6), wherein the intermixed region (44) is arranged below the first contact (1) in the vertical direction. Further, a method for producing the optoelectronic component (10) is specified.

### CROSS-REFERENCE TO RELATED APPLICATIONS

This patent application is a national stage entry from International Application No. PCT/EP2020/080735, filed on Nov. 3, 2020, published as International Publication No. WO 2021/099100 A2 on May 27, 2021, and claims priority to German Patent Application No. 10 2019 131 422.4, filed Nov. 21, 2019, the entire contents of all of which are incorporated by reference herein.

### FIELD OF THE INVENTION

The invention relates to an optoelectronic component and a method for producing the optoelectronic component.

### BACKGROUND OF THE INVENTION

In optoelectronic components, in particular in LEDs, at least one of the electrical contacts may be provided on a radiation exit surface of the semiconductor body. If a metal is used to produce the electrical contact to the semiconductor body, the electrical contact may reduce light extraction because light originating under the metal contact cannot leave the semiconductor body through the metal.

An object to be solved is to specify an improved optoelectronic component in which, in particular, light extraction is impaired as little as possible by a metal contact at the radiation exit surface. Furthermore, a method suitable for producing the optoelectronic component is to be specified.

These objects are solved by an optoelectronic component and a method for producing it according to the independent patent claims. Advantageous embodiments and further embodiments of the invention are the subject of the dependent claims.

### SUMMARY OF THE INVENTION

According to at least one embodiment, the optoelectronic component comprises a semiconductor body with an active layer suitable for emitting radiation, which comprises a quantum well structure. The quantum well structure may be a single or multiple quantum well structure. The quantum well structure includes at least one quantum well layer arranged between barrier layers. In the case of a multiple quantum well structure, the quantum well structure includes alternating quantum well layers and barrier layers. The number of quantum well layers is, for example, between 1 and 100, preferably between 5 and 10. The barrier layers comprise a larger electronic band gap than the at least one quantum well layer. The active layer is arranged, for example, between a p-type semiconductor region and an n-type semiconductor region of the semiconductor body.

The optoelectronic component comprises a first electrical contact and a second electrical contact. The first electrical contact and the second electrical contact are provided for forming a current path through the semiconductor body.

According to at least one embodiment of the optoelectronic component, the quantum well structure comprises at least one intermixed region and at least one non-intermixed region. The at least one quantum well layer and the barrier layers are at least partially or even completely intermixed in the intermixed region. By intermixing the quantum well structure, the intermixed region comprises a larger electronic bandgap than the at least one quantum well layer in the non-intermixed region.

According to at least one embodiment, the first electrical contact is a metal contact arranged on a radiation exit surface of the semiconductor body. In particular, the first electrical contact may comprise a metal or a metal alloy with good electrical conductivity, such as gold, silver, aluminum, titanium or platinum, or an alloy of these metals. It is also possible that the first contact comprises a layer sequence of several metal layers, for example a Ti/Pt/Au layer sequence. The aforementioned materials can also be used for the second electrical contact. In particular, the second electrical contact may be arranged on a main surface of the semiconductor body opposite the radiation exit surface. The optoelectronic component is in particular a so-called vertical LED, in which the current flow through the semiconductor body is from the first electrical contact at the radiation exit surface to the second electrical contact at a main surface of the semiconductor body opposite the radiation exit surface.

According to at least one embodiment, the intermixed region of the quantum well structure is arranged in the vertical direction below the first electrical contact. Here, the vertical direction is understood to be the direction perpendicular to the layer planes of the semiconductor body. The first electrical contact need not be directly adjacent to the intermixed region; rather, at least one semiconductor layer may be arranged between the first electrical contact and the intermixed region. “Below the first contact” particularly means that the first contact is not laterally offset from the intermixed region. In particular, the first contact and the intermixed region may be arranged centered with respect to each other in the lateral direction.

Preferably, the first electrical contact and the intermixed region comprise the same shape and/or width. In particular, the first electrical contact and the intermixed region may be congruent when viewed from above the semiconductor body. In the optoelectronic component, the non-intermixed regions of the quantum well structure are advantageously arranged offset in the lateral direction from the first contact.

In particular, the optoelectronic component described herein makes use of the idea that radiative recombination of charge carriers is reduced in the intermixed region below the first electrical contact. Charge carriers injected into the active layer from the electrical contacts do not recombine below the first contact arranged on the radiation exit surface due to the increased electronic band gap in the intermixed region, but diffuse into the non-intermixed regions with the smaller electronic band gap and recombine there. In this way, less radiation is generated below the first electrical contact, reducing the absorption of radiation in the first electrical contact. The light extraction from the optoelectronic component is thus advantageously increased.

According to at least one embodiment, the width of the intermixed region is less than 10 μm and preferably less than 2 μm. A small width of the intermixed region is advantageous to allow as many electrons and holes as possible to diffuse into the regions that are not intermixed. In particular, it is advantageous if the width of the intermixed region is smaller than the diffusion length of the electrons and holes in the semiconductor body. Preferably, the width of the first electrical contact is substantially equal to the width of the intermixed region, for example, the width of the first electrical contact is between 0.8 times and 1.2 times, preferably between 0.9 times and 1.1 times the width of the intermixed region. Particularly preferably, the widths of the first electrical contact and the intermixed region are the same. Preferably, the width of the intermixed region is less than 10 μm and preferably less than 2 μm. For example, the intermixed region and/or the first electrical contact are between 100 nm and 10 μm wide, preferably between 1 μm and 2 μm wide.

According to at least one embodiment, the electronic band gap in the intermixed region is larger than in the non-intermixed region by at least 0.05 eV, at least 0.08 eV or even by at least 0.1 eV. For example, the electronic band gap in the intermixed region is between 0.05 eV and 0.3 eV, preferably between 0.08 eV and 0.1 eV larger than in the non-intermixed region.

According to at least one embodiment, the first electrical contact is an n-contact and the second electrical contact is a p-contact of the semiconductor body. The semiconductor body is, for example, a so-called thin film semiconductor body. In producing a thin-film semiconductor body, a functional semiconductor layer sequence, which in particular comprises the radiation-emitting active layer, is first epitaxially grown on a growth substrate, then a carrier is applied to the surface of the semiconductor layer sequence opposite to the growth substrate, and subsequently the growth substrate is removed. Since the growth substrates used for nitride compound semiconductors, for example SiC, sapphire or GaN, are comparatively expensive, this method offers the advantage that the growth substrate is reusable. The detachment of a growth substrate made of sapphire from a semiconductor layer sequence made of a nitride compound semiconductor can be done, for example, with a laser lift-off method. In a thin film semiconductor body, typically the p-type semiconductor region faces the support substrate and the n-type semiconductor region originally grown first on the growth substrate faces the radiation exit surface.

According to at least one embodiment, the second electrical contact is arranged on a main surface of the semiconductor body opposite the radiation exit surface. Thus, the current path through the semiconductor body leads from the radiation exit surface to the opposite main surface of the semiconductor body.

According to at least one embodiment, the semiconductor body is based on an arsenide compound semiconductor material, a phosphide compound semiconductor material, or a nitride compound semiconductor material. For example, the semiconductor body may include InₓAl_{y}Ga_{1-x-y}As, InₓAl_{y}Ga_{1-x-y}P or InₓAl_{y}Ga_{1-x-y}N, each with 0≤x≤1, 0≤y≤1, and x+y≤1. In this regard, the III-V compound semiconductor material need not necessarily comprise a mathematically exact composition according to one of the above formulas. Rather, it may comprise one or more dopants as well as additional constituents. However, for simplicity, above formulas include only the essential constituents of the crystal lattice, even though these may be partially replaced by small amounts of additional substances.

According to at least one embodiment, the intermixed region and the non-intermixed region comprise substantially the same dopant concentration. In particular, the intermixed region and the non-intermixed region are nominally equally doped, i.e., foreign atoms are not selectively incorporated into the intermixed region. In particular, this can be achieved by producing the intermixed region by an impurity free quantum well intermixing process.

According to at least one embodiment, the optoelectronic component is an LED. For example, the LED may emit light in the visible spectral range or in the adjacent UV or IR spectral range.

A method for producing the optoelectronic component is further specified. According to at least one embodiment, the method comprises a first step of producing a semiconductor body with an active layer suitable for emitting radiation, wherein the active layer comprises a quantum well structure. The quantum well structure may be a single or multiple quantum well structure. The quantum well structure includes at least one quantum well layer arranged between barrier layers. In the case of a multiple quantum well structure, the quantum well structure includes alternating quantum well layers and barrier layers.

According to at least one embodiment, with the method a dielectric layer is applied to a contact region of the semiconductor body. The contact region is a region of the semiconductor body to which a metallic first electrical contact is applied in a subsequent method step. The dielectric layer comprises a coefficient of thermal expansion different from that of the semiconductor body, in particular a smaller coefficient of thermal expansion. When the temperature is increased, the different coefficients of thermal expansion of the dielectric layer and the adjacent semiconductor body cause thermal stress. For example, a compressive strain in the semiconductor material occurs when the dielectric layer comprises a smaller coefficient of thermal expansion than the semiconductor body.

Subsequently, a thermal treatment is performed to diffuse atoms from the semiconductor body into the dielectric layer, creating vacancies in the semiconductor body. The diffusion of atoms from the semiconductor material into the dielectric layer is driven by the compressive thermal stress in the semiconductor material created during the temperature treatment.

The vacancies left by the atoms diffused into the dielectric layer can be occupied by other atoms, which in turn leave vacancies. In this way, it is achieved that vacancies virtually diffuse in the semiconductor body. A diffusion of the vacancies in the semiconductor body creates an intermixed region in the quantum well structure, wherein the at least one quantum well layer and the barrier layers are at least partially intermixed in the intermixed region. In this way, the intermixed region is made to comprise a larger electronic bandgap than the at least one quantum well layer in the non-intermixed region.

In a further step of the method, the dielectric layer is removed from the contact region of the semiconductor body. Subsequently, a metal layer is applied to the contact region of the semiconductor body. In this way, the first electrical contact is formed in the contact region, which is arranged above the intermixed region of the quantum well structure.

According to at least one embodiment, the dielectric layer is a SiO₂ layer. SiO₂ comprises a lower coefficient of thermal expansion compared to III- semiconductor materials such as arsenide, phosphide or nitride compound semiconductor materials. Therefore, the semiconductor body is compressively strained during the thermal treatment.

According to at least one embodiment, the semiconductor body comprises a Ga-containing semiconductor material, wherein Ga atoms diffuse from the semiconductor body into the dielectric layer during the temperature treatment. It has been found that the diffusion of Ga atoms from a semiconductor material such as Ga(In, Al)As or Ga(In, Al)P can be caused by a compressive strain, which can be generated in particular with a SiO₂ layer. The Ga atoms leave vacancies in the semiconductor material, which subsequently diffuse through the semiconductor material and in this way in particular create the intermixed region.

According to at least one embodiment, the temperature treatment is performed at a temperature of at least 700° C., at least 800° C. or even at least 900° C. In particular, the temperature treatment can be carried out in the temperature range from 700° C. to 1200° C., preferably in the range from 800° C. to 1000° C., for example at about 900° C. With such a high temperature, a mechanical stress can be caused between the dielectric layer and the semiconductor body, which stimulates diffusion of atoms from the semiconductor body into the dielectric layer. The duration of the temperature treatment is about 10 s to 10 min, preferably 1 min to 2 min.

According to at least one embodiment, next to the dielectric layer, a further dielectric layer is applied to the semiconductor body, which comprises a larger coefficient of thermal expansion than the semiconductor body. In the region of the further dielectric layer, therefore, no compressive stress is created, but rather a tensile stress. Diffusion of atoms from the semiconductor body and the resulting intermixing of the quantum well structure are thus reduced or even completely prevented. In the method, the further dielectric layer is removed from the semiconductor body again, for example, together with the dielectric layer.

Preferably, the further dielectric layer is a SrF₂ layer. SrF₂ is characterized by a large coefficient of thermal expansion. This material is particularly well suited to reduce the thermally induced compressive stress outside the region of the dielectric layer, for example a SiO₂ layer, and thus to reduce the diffusion of atoms from the semiconductor body in this region.

### BRIEF DESCRIPTION OF THE DRAWINGS

The invention is explained in more detail below by means of exemplary embodiments in connection with FIGS. 1 and 2.

In the Figures:

FIG. 1A shows a schematic illustration of a cross-section through an example of the optoelectronic component,

FIG. 1B shows a schematic detail view of the active layer in the non-intermixed region in the example of the optoelectronic component,

FIG. 1C shows a schematic illustration of the course of the electronic bandgap of the active layer in the lateral direction in the example of the optoelectronic component, and

FIGS. 2A to 2D show a schematic illustration of an example of the method for producing the optoelectronic component.

### DETAILED DESCRIPTION

Components that are the same or have the same effect are each provided with the same reference signs in the figures. The components shown and the proportions of the components to one another are not to be regarded as true to scale.

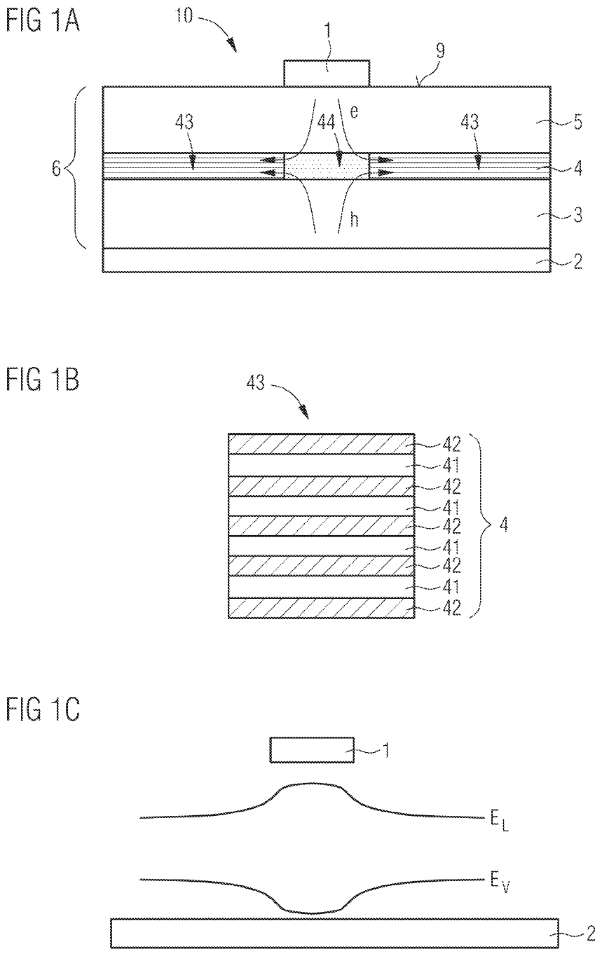

FIG. 1A illustrates an example of the optoelectronic component 10. The optoelectronic component 10 may in particular be an LED. The optoelectronic component 10 comprises a semiconductor body 6 which comprises a p-type semiconductor region 3, an n-type semiconductor region 5 and an active layer 4 arranged between the p-type semiconductor region 3 and the n-type semiconductor region 5. In particular, the active layer 4 is a radiation-emitting active layer 4. The p-type semiconductor region 3 and the n-type semiconductor region 5 may each include one or more semiconductor layers. The p-type semiconductor region 3 includes one or more p-doped semiconductor layers, and the n-doped semiconductor region 5 includes one or more n-doped semiconductor layers. It is also possible that the p-type semiconductor region 3 and/or the n-type semiconductor region 5 include one or more undoped semiconductor layers.

The semiconductor body 6 of the optoelectronic component 10 is preferably based on a III-V compound semiconductor material, in particular on an arsenide, phosphide or nitride compound semiconductor material. In this case, the material is selected based on the desired emission wavelength of the optoelectronic component 10.

For example, with a nitride compound semiconductor material, radiation in the UV, blue, and green spectral ranges can be generated. With a phosphide compound semiconductor material, for example, radiation in the green to red spectral range can be generated. For example, with an arsenide compound semiconductor material, radiation in the red to infrared spectral range can be generated.

For example, the semiconductor body 6 may include InₓAl_{y}Ga_{1-x-y}As, InₓAl_{y}Ga_{1-x-y}P or InₓAl_{y}Ga_{1-x-y}N, each with 0≤x≤1, 0≤y≤1, and x+y≤1. In this regard, the III-V compound semiconductor material need not necessarily comprise a mathematically exact composition according to any of the above formulas. Rather, it may comprise one or more dopants as well as additional constituents. For simplicity, however, the above formulas include only the essential constituents of the crystal lattice, even though these may be partially replaced by small amounts of additional substances.

The active layer 4 of the optoelectronic component 10 is a quantum well structure comprising a non-intermixed region 43 and an intermixed region 44. A detailed view of the active layer 4 in the non-intermixed region 43 is shown in FIG. 1B. The active layer 4 comprises alternating quantum well layers 41 and barrier layers 42. The barrier layers 42 comprise a larger electronic band gap than the quantum well layers 41.

The quantum well layers 41 and barrier layers 42 of the active layer 4 are at least partially intermixed in an intermixed region 44 in the optoelectronic component 10 shown in FIG. 1A. In the intermixed region 44, in particular, the semiconductor material of the quantum well layers 41 is at least partially intermixed with the semiconductor material of the barrier layers 42, which comprises the larger electronic band gap. As a result, the active layer 4 in the intermixed region 44 comprises a larger electronic band gap than the quantum well layers 41 in the non-intermixed region 43.

The optoelectronic component 10 comprises a first electrical contact 1 and a second electrical contact 2 for electrical contacting. For example, the first electrical contact is the p-contact and the second electrical contact 2 is the re-contact of the optoelectronic component 10. The first electrical contact 1 is a metal contact arranged at a radiation exit surface 9 of the optoelectronic component 10. The first electrical contact 1 and/or the second electrical contact 2 may in particular each comprise a metal such as, for example, gold, silver, aluminum, titanium or platinum, or an alloy or a layer sequence of these metals.

In the optoelectronic component 10, the intermixed region 44 of the active layer 4 is arranged below the first electrical contact 1. Preferably, the intermixed region 44 comprises substantially the same width as the first electrical contact 1. In particular, the intermixed region 44 is arranged centered below the first electrical contact 1. In the perpendicular direction, the intermixed region 44 is not directly adjacent to the first electrical contact 1, but is spaced apart from the first electrical contact 1 by, for example, one or more semiconductor layers of the n-type semiconductor region 5.

The arrangement of the intermixed region 44 below the first electrical contact 1 has the advantage that the electronic band gap is increased in this region. The course of the electronic band gap in the lateral direction in the example of the optoelectronic component 10 is schematically illustrated in FIG. 1C. In the region below the first electrical contact 1, the distance between the conduction band edge E_{L} and the valence band edge E_{B}, and thus the electronic band gap, is increased compared to the neighboring non-intermixed regions of the quantum well structure. Preferably, the electronic band gap in the intermixed region below the first electrical contact is larger than in the non-intermixed region by at least 0.05 eV, for example between 0.05 eV and 0.3 eV and preferably between 0.08 eV and 0.1 eV. The increased electronic band gap in the intermixed region can be detected, for example, by measuring the photoluminescence in this region.

As can be seen in FIG. 1A, the enlarged electronic band gap in the intermixed region 44 causes electrons e moving from the first electrical contact 1 to the active zone 4 and holes h moving from the second electrical contact 2 toward the active zone 4 to substantially not recombine with each other in the intermixed region 44. Instead, the electrons e and the holes h diffuse, as outlined by arrows in FIG. 1A, into the adjacent non-intermixed regions 43 and recombine only there with the emission of radiation.

In order to diffuse as many electrons and holes as possible into the non-intermixed regions 43, it is advantageous if the width of the intermixed region 44 is smaller than the diffusion length of the charge carriers e, h in the semiconductor body. Therefore, the semiconductor body 6 is advantageously based on a material system with large carrier diffusion length such as GaAs, InAlGaAs, InGaAlP or InP. However, the intermixed region 44 can also be implemented in nitride semiconductor materials such as InGaN, GaN or AlGaN.

Preferably, the width of the intermixed region 44 and/or the first contact 1 is less than 10 μm and more preferably less than 2 μm. For example, the width of the intermixed region and/or the first contact is between 100 nm and 10 μm, preferably between 1 μm and 2 μm.

The reduced recombination of charge carriers in the region below the first electrical contact 1 has the advantage that less radiation is generated below the first electrical contact 1 which could be absorbed at the first electrical contact 1. Rather, the recombination of charge carriers and thus the emission of radiation occurs more in the non-intermixed regions 43 above which no electrical contact is arranged and thus the radiation exit surface 9 is exposed. Light extraction from the optoelectronic component 10 is improved in this way.

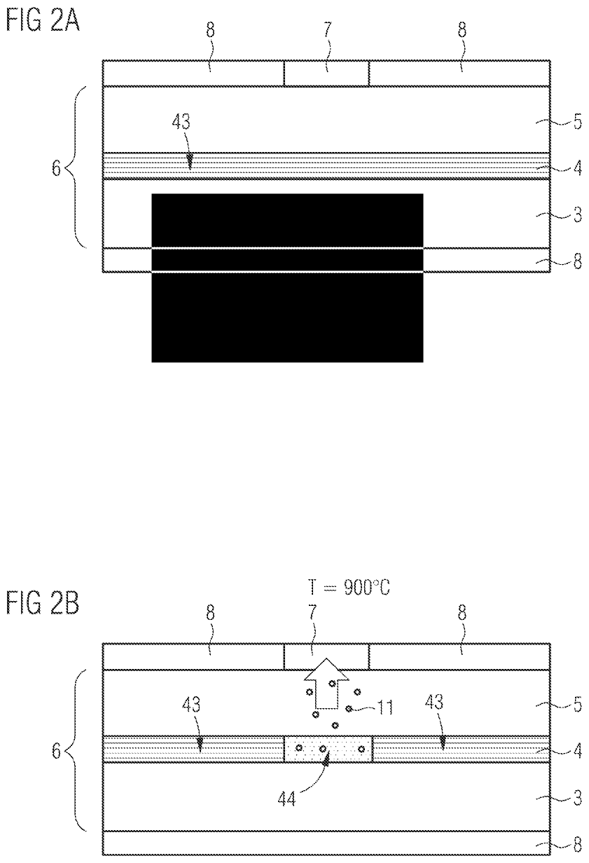

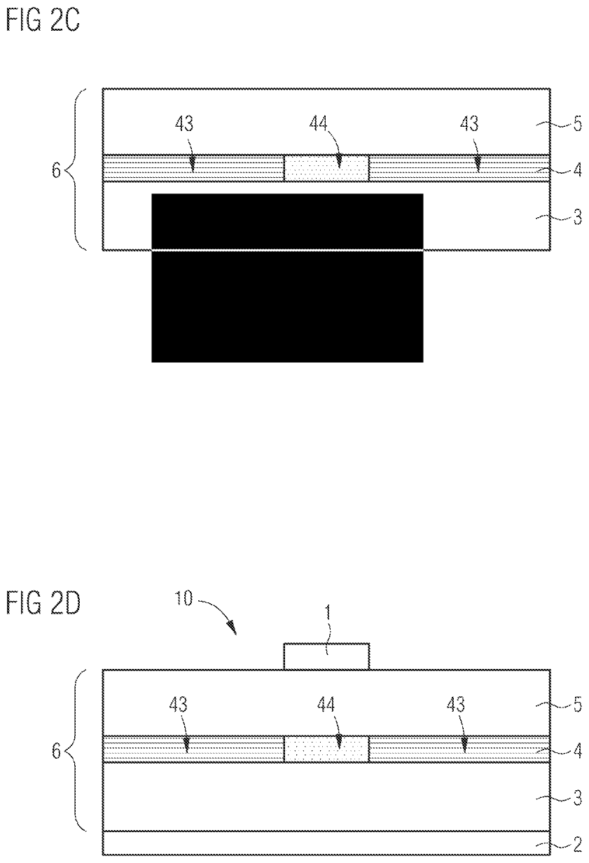

In the following FIGS. 2A to 2D, a method for producing the optoelectronic component 10 by means of intermediate steps is illustrated by way of example.

In the intermediate step shown in FIG. 2, a semiconductor body 6 has been produced which comprises the p-type semiconductor region 3, the active layer 4 formed as a quantum well structure, and the n-type sub region 5. The active layer 4 comprises alternating quantum well layers and barrier layers as described above in connection with FIG. 1B.

A dielectric layer 7, which comprises a coefficient of thermal expansion different from that of the semiconductor body 6, has been applied to a contact region of the semiconductor body 6, the contact region being a region of the surface of the semiconductor body 6 to which the first electrical contact is to be applied in a subsequent method step. The dielectric layer 7 is, for example, a SiO₂ layer. The coefficient of thermal expansion of SiO₂ is lower than the coefficient of thermal expansion of III-V semiconductor materials such as arsenide, phosphide or nitride compound semiconductor materials. For example, the coefficient of thermal expansion of SiO₂ is about 0.5*10⁻⁶/K and the coefficient of thermal expansion of GaAs is about 6*10⁻⁶/K. Thus, the thermal expansion of the semiconductor material is much larger than the thermal expansion of the dielectric layer 7.

On the regions of the surface of the semiconductor body 6, which are arranged adjacent to the dielectric layer 7, a further dielectric layer 8 can be applied, which comprises a larger coefficient of thermal expansion than the dielectric layer and the semiconductor body. The further dielectric layer 8 is, for example, a SrF₂ layer. It is possible that the further dielectric layer 8 is also applied to an opposite surface of the semiconductor body 6.

In a further step, which is schematically illustrated in FIG. 2B, a temperature treatment of the semiconductor body 6 is performed. The temperature treatment may be carried out in the temperature range of about 700° C. to 1200° C., for example, at a temperature of about 900° C. The temperature treatment lasts, for example, from 10 s to 10 min, preferably from about 1 min to 2 min. Due to the different coefficients of thermal expansion of the semiconductor body 6 and the dielectric layer 7, a stress is generated between the materials of the dielectric layer 7 and the semiconductor body 6 in the region of the dielectric layer 7.

In particular, in the case of a dielectric layer made of SiO₂, a large compressive stress is created in the semiconductor body due to the thermal treatment. The thermally induced strain causes atoms 11 to move from the semiconductor body 6 into the dielectric layer 7. For example, gallium atoms 11 may diffuse from the semiconductor material of the semiconductor body 6 into the dielectric layer 7 during the thermal treatment. The atoms 11 diffused from the semiconductor body 6 leave vacancies that diffuse in the semiconductor body 6. By the diffusion of the vacancies the quantum well layers and barrier layers are at least partially intermixed in the region below the dielectric layer 7, creating the intermixed region 44 in the active layer 4.

In the regions of the semiconductor body 6 arranged laterally from the dielectric layer 7, in which a SrF₂ layer is arranged as a further dielectric layer 8, the thermal stress is substantially lower due to the larger coefficient of thermal expansion of the further dielectric layer 8 and therefore causes substantially no diffusion of atoms of the semiconductor body 6 into the further dielectric layer 8. Outside the region of the dielectric layer 7, therefore, substantially no vacancy diffusion takes place, so that the active layer 4 is not intermixed there. After the temperature treatment, therefore, outside the contact region of the semiconductor body 6 to which the dielectric layer 7 is applied, there are regions 43 of the active layer 4 which are not intermixed.

In the example described here, the production of the intermixed region 44 in the active layer 4 is advantageously carried out by a thermally induced diffusion process in which no foreign atoms are introduced into the intermixed region 44. The doping of the semiconductor body 6 is therefore not deliberately changed during the production of the intermixed region 44. In particular, the non-intermixed regions 43 and the intermixed region 44 of the active layer 4 nominally comprise the same or no doping.

In a further intermediate step of the method, which is schematically illustrated in FIG. 2C, the dielectric layer 7 and the further dielectric layer 8 have been removed again from the semiconductor body 6. This can be done, for example, with an etching process suitable for this purpose.

In a next step of the method, which is illustrated in FIG. 2D, the first electrical contact 1 and the second electrical contact 2 have been applied to the semiconductor body 6. The first electrical contact 1 is applied to the contact region of the semiconductor body 6 on which the dielectric layer 7 was previously arranged. In this way, it is achieved that the intermixed region 44 is arranged below the first electrical contact 1.

Preferably, the first electrical contact 1 is applied in such a way that the shape and/or width of the first electrical contact 1 substantially correspond to the shape and/or width of the intermixed region 44. Particularly preferably, the first electrical contact 1 and the intermixed region 44 are congruent when viewed from above the semiconductor body 6. The first electrical contact 1 is, for example, the n-contact of the optoelectronic component.

The second electrical contact 2 is applied to a surface of the semiconductor body 6 opposite to the first electrical contact 2. The second electrical contact 2 may, for example, be applied over the entire surface of the main surface of the semiconductor body opposite the radiation exit surface 9. The second electrical contact 2 may, for example, be designed as a mirror contact comprising a material reflective of the radiation emitted by the active layer 4, such as silver or aluminum. It is possible that the second electrical contact 2 is arranged between the semiconductor body 6 and a carrier (not illustrated) of the semiconductor body 6. The second electrical contact 2 is, for example, the p-contact of the optoelectronic component 10.

The invention is not limited by the description based on the exemplary embodiments. Rather, the invention encompasses any new feature as well as any combination of features, which in particular includes any combination of features in the patent claims, even if that feature or combination itself is not explicitly specified in the claims or exemplary embodiments.

1. An optoelectronic component, comprising
a semiconductor body with an active layer suitable for emitting radiation and comprising a quantum well structure, wherein the quantum well structure comprises at least a quantum well layer and barrier layers.
a first electrical contact and a second electrical contact, wherein
the active region comprises at least one intermixed region and at least one non-intermixed region
the at least one quantum well layer and the barrier layers in the intermixed region are at least partially intermixed, so that the intermixed region comprises a larger electronic bandgap than the at least one quantum well layer in the non-intermixed region,
the first electrical contact is a metal contact arranged on a radiation exit surface of said semiconductor body, and
the intermixed region is arranged below the first contact (1) in the vertical direction, and
the intermixed region comprises a width of less than 10 μm.

2. The optoelectronic component according to claim 1, wherein the first contact comprises a width of less than 10 μm.

3. The optoelectronic component according to claim 1, wherein the electronic bandgap in the intermixed region is larger by at least 0.05 eV than in the non-intermixed region.

4. The optoelectronic component according to claim 1, wherein the first contact is an n-contact and the second contact is a p-contact of the semiconductor body.

5. The optoelectronic component according to claim 1, wherein the second contact is arranged on a main surface of the semiconductor body opposite the radiation exit surface.

6. The optoelectronic component according to claim 1, wherein the semiconductor body is based on an arsenide compound semiconductor material, a phosphide compound semiconductor material or a nitride compound semiconductor material.

7. The optoelectronic component according to claim 1, wherein the intermixed region and the non-intermixed region comprise the same dopant concentration.

8. The optoelectronic component according to claim 1, wherein the optoelectronic component is an LED.

9. A method for producing an optoelectronic component, comprising:
producing a semiconductor body with an active layer suitable for emitting radiation and comprising a quantum well structure, wherein the quantum well structure comprises at least one quantum well layer and barrier layers,
applying a dielectric layer to a contact region of the semiconductor body, wherein the dielectric layer comprises a coefficient of thermal expansion different from that of the semiconductor body,
perform a thermal treatment wherein atoms diffuse from the semiconductor body into the dielectric layer and create vacancies in the semiconductor body, wherein a diffusion of the vacancies in the semiconductor body creates a intermixed region in the active layer and wherein the at least one quantum well layer and the barrier layers are at least partially intermixed in the intermixed region such that the intermixed region comprises a larger electronic bandgap than the at least one quantum well layer in the non-intermixed region and the intermixed region comprises a width of less than 10 μm,
removing the dielectric layer from the contact region of the semiconductor body, and
applying a metal layer to the contact region of the semiconductor body to form a first electrical contact in the contact region.

10. The method according to claim 9, wherein the dielectric layer is a SiO₂ layer.

11. The method according to claim 9, wherein the semiconductor body comprises a Ga-containing semiconductor material, and wherein Ga atoms diffuse from the semiconductor body into the dielectric layer during the temperature treatment.

12. The method according to claim 9, wherein the temperature treatment is performed at a temperature of at least 700° C.

13. The method according to claim 9, wherein, next to the dielectric layer, a further dielectric layer is applied to the semiconductor body, which comprises a larger coefficient of thermal expansion than the semiconductor body.

14. The method according to claim 13, wherein the further dielectric layer is a SrF₂ layer.
